(19) United States
(12) Patent Application Publication
(10) Pub. No.: US 2024/0341072 A1
(43) Pub. Date: Oct. 10, 2024

(54) MOUNTING DEVICE, MOUNTING SYSTEM, AND SETTING METHOD

(71) Applicant: FUJI CORPORATION, Chiryu (JP)

(72) Inventor: Takeshi SAKURAYAMA, Nisshin-shi (JP)

(73) Assignee: FUJI CORPORATION, Chiryu (JP)

(21) Appl. No.: 18/681,724

(22) PCT Filed: Sep. 1, 2021
(86) PCT No.: PCT/JP2021/032112

§ 371 Date: Feb. 6, 2024

(51) Int. Cl. H05K 13/08

(52) U.S. Cl. CPC H05K 13/0882; H05K 13/081

(57) ABSTRACT

A mounting device according to the present disclosure includes a component supply section configured to supply a component from a holding member that holds multiple components; a mounting section including a collection member configured to collect the component from the component supply section, the mounting section being capable of collecting the component at multiple collection heights; and a control section configured to perform a predetermined allowance determination by causing the mounting section to collect the component at a predetermined collection height within a range of a predetermined number of short-term components, execute a changing process of repeatedly changing the collection height using a short-term offset value for adjusting the collection height of the mounting section when the number of collection errors exceeds the predetermined number of allowances, and execute a short-term evaluation setting process of setting the collection height based on a result of the changing process.

### TECHNICAL FIELD

The present description discloses a mounting device, a mounting system, and a setting method.

### BACKGROUND ART

Conventionally, as a mounting device, a mounting device, which specifies positional information of an electronic component on which components are held or mounted using a mounting condition including a height, specifies a variation in a position of the electronic component for each mounting condition using multiple specified positional information, and specifies a new mounting condition of the electronic component using the specified variation, has been proposed (for example, see Patent Literature 1 or the like). In the device, it is assumed that the accuracy of holding or mounting the component can be improved by changing a height of a suction nozzle or the like in accordance with the positional deviation of the component when holding and mounting the component. In addition, as a mounting device, a mounting device, which calculates a difference between a representative value of a dimension of an electronic component in a product lot of a target of pickup and conveyance and a reference dimension of the electronic component, sets a lowering amount of a tip of a suction nozzle with respect to the product lot based on the difference, calculates a predicted value of an occurrence probability of an error in which the suction nozzle and the electronic component in the product lot come into contact with each other, estimates a bias of the difference from an actual value of the occurrence probability of the error and the predicted value, and corrects the lowering amount of the tip of the suction nozzle based on the bias of the estimated difference, has been proposed (for example, see Patent Literature 2 or the like). In this device, stability of pickup and conveyance can be improved. In addition, as a mounting device, a mounting device, which performs a process of mounting a component on a board, and then mounts a component under a mounting condition for preventing the component from being brought back when mounting a component that is likely to be brought back with the component still attached to a nozzle, has been proposed (for example, see Patent Literature 3 or the like).

### PATENT LITERATURE

Patent Literature 1: JP-A-2014-96509
Patent Literature 2: JP-A-2016-187016
Patent Literature 3: JP-A-2007-250795

### BRIEF SUMMARY

### Technical Problem

However, in Patent Literature 1 described above, the height of the suction nozzle is changed to improve the accuracy of the holding and mounting of the component, but the accuracy evaluation in a shorter period of time is not considered. Even in Patent Literatures 2 and 3, the accuracy evaluation in a shorter period of time is not considered.

The present disclosure has been made in view of such a problem, and a main object of the present disclosure is to provide a mounting device, a mounting system, and a setting method capable of further improving collection accuracy of components in short-term evaluation.

### Solution to Problem

The present disclosure employs the following means in order to achieve the above-described main object.

A mounting device according to the present disclosure includes a component supply section configured to supply a component from a holding member that holds multiple components;

a mounting section including a collection member configured to collect the component from the component supply section, the mounting section being capable of collecting the component at multiple collection heights; and a control section configured to perform a predetermined allowance determination by causing the mounting section to collect the component at a predetermined collection height within a range of a predetermined number of short-term components, execute a changing process of repeatedly changing the collection height using a short-term offset value for adjusting the collection height of the mounting section when the number of collection errors exceeds a predetermined number of allowances, and execute a short-term evaluation setting process of setting the collection height based on a result of the changing process.

The mounting device performs an allowance determination to determine whether the number of collection errors exceeds the predetermined number of allowances within the range of the predetermined number of short-term components, and executes the short-term evaluation setting process to set the collection height based on the result of the changing process to change the collection height. Generally, in the mounting device, a large number of component statistics may be required in order to improve the collection accuracy in the production process. In the mounting device, since a suitable collection height is set by changing the collection height within the range of the predetermined number of short-term components, it is possible to further improve the collection accuracy of the component in the short-term evaluation.

### BRIEF DESCRIPTION OF DRAWINGS

FIG. 1 is a schematic diagram illustrating an example of mounting system 10.

FIG. 2 is a diagram illustrating an example of mounting section 20 and component supply section 14.

FIG. 3 is a diagram illustrating an example of information stored in storage section 33.

FIG. 4 is a flowchart illustrating an example of a mounting process routine.

FIG. 5 is a diagram illustrating an example of collection accuracy.

FIG. 6 is a flowchart illustrating an example of an evaluation setting process routine.

FIG. 7 is a flowchart illustrating an example of a height changing process routine.

FIG. 8 is a diagram of allowable ranges of short-term adjustment width Af and production adjustment width Ap.

### DESCRIPTION OF EMBODIMENTS

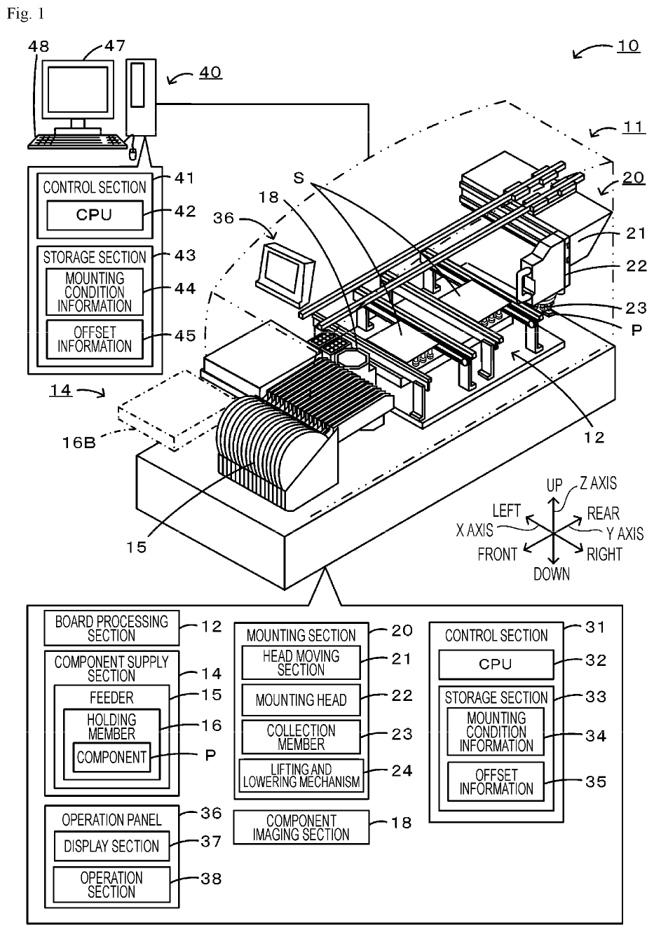

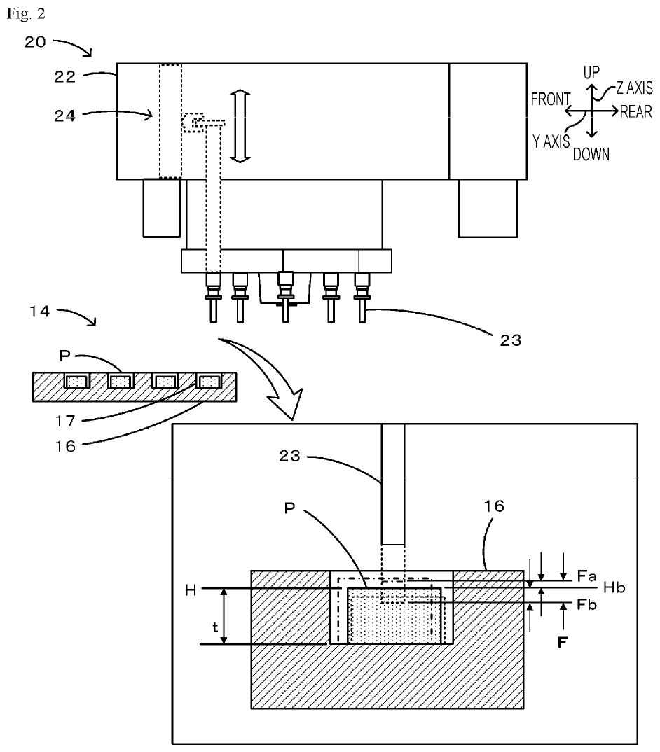

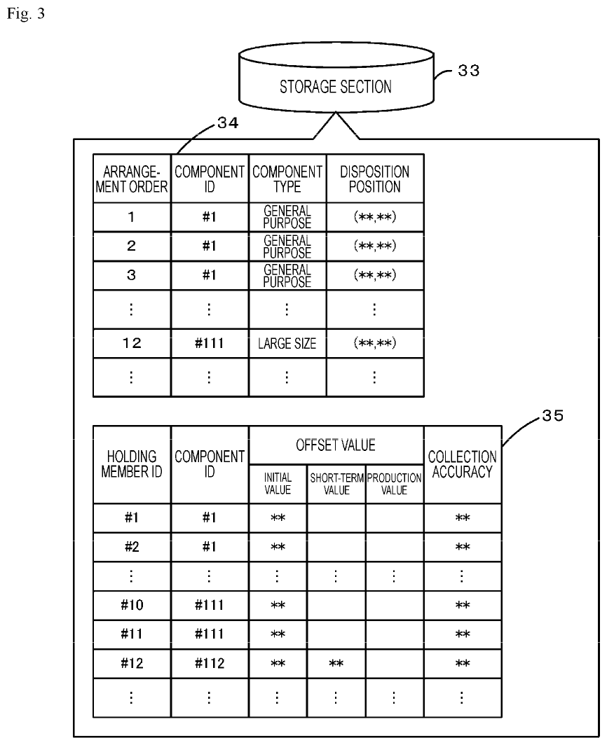

Hereinafter, the present embodiment will be described with reference to the drawings. FIG. 1 is a schematic diagram of mounting system 10 that is an example of the present disclosure. FIG. 2 is a diagram illustrating an example of mounting section 20 and component supply section 14. FIG. 3 is a diagram illustrating an example of mounting condition information 34 and offset information 35 stored in storage section 33. Mounting system 10 is configured, for example, as a production line in which mounting devices 11 that perform a mounting process of component P on board S serving as a process target object are arranged in a conveyance direction of board S. Here, the process target object will be described as board S, but the process target object is not particularly limited as long as the process target object is a board on which component P is mounted, and may be a base material having a three-dimensional shape. As illustrated in FIG. 1, mounting system 10 includes mounting device 11, management device 40, or the like. In FIG. 1, only one mounting device 11 is illustrated. In the present embodiment, a left-right direction (X-axis), a front-rear direction (Y-axis), and an up-down direction (Z-axis) are as illustrated in FIGS. 1 and 2.

As illustrated in FIG. 1, mounting device 11 includes board processing section 12, component supply section 14, component imaging section 18, mounting section 20, control section 31, and operation panel 36. Board processing section 12 is a unit that carries in board S, conveys board S, fixes board S at a mounting position, and carries out board S. Board processing section 12 has two pairs of conveyor belts that are provided with intervals in the front-rear direction in FIG. 1 and built in the left-right direction. Board S is conveyed by the conveyor belts.

Component supply section 14 is a unit that supplies component P to mounting section 20. Component supply section 14 includes multiple feeders 15 on which reels on which holding members 16 (tape members) holding components are wound are mounted. Holding member 16 is formed with holding sections 17 serving as accommodation cavities at equal intervals, and component P is held by holding section 17. In addition, component supply section 14 includes a tray unit having holding member 16B (tray) on which multiple components P are arranged and placed.

Component imaging section 18 is a device that captures an image of one or more components P, which are collected and held by mounting head 22, from below. Component imaging section 18 captures the image of component P when mounting head 22 that collects component P passes above component imaging section 18, and outputs the captured image to control section 31. Control section 31 detects a collection state of component P using the captured image.

Mounting section 20 is a unit that collects component P from component supply section 14 and disposes component P on board S fixed to board processing section 12. Mounting section 20 includes head moving section 21, mounting head 22, and collection member 23. In addition, mounting section 20 includes lifting and lowering mechanism 24 and measurement section 25. Head moving section 21 includes a slider that moves in XY directions while being guided by guide rails and a motor for driving the slider. Mounting head 22 collects one or more components P and moves in the XY directions by means of head moving section 21. Mounting head 22 is detachably mounted on the slider. One or more collection members 23 are detachably mounted on a lower surface of mounting head 22. Collection member 23 is a nozzle that collects component P using a negative pressure. The collection member that collects component P may be a mechanical chuck or the like that mechanically grips component P, in addition to collection member 23.

As illustrated in FIG. 2, lifting and lowering mechanism 24 is a device that engages with a flange portion of a cylinder on which collection member 23 is mounted and moves up and down collection member 23 in the up-down direction. Lifting and lowering mechanism 24 may be a ball screw mechanism or a linear motor. Lifting and lowering mechanism 24 can finely adjust the position of the tip of collection member 23 in the up-down direction when collection member 23 is lowered to the maximum. Mounting section 20 may be provided with a height adjusting section for vertically moving mounting head 22 to finely adjust the position of the tip of collection member 23 in the up-down direction. Thus, mounting section 20 is configured to be able to collect components P at multiple collection heights.

Control section 31 is configured as a microprocessor centered on CPU 32, and includes storage section 33 that stores various data and the like. Control section 31 outputs control signals to board processing section 12, component supply section 14, component imaging section 18, operation panel 36, and mounting section 20, and inputs signals from component supply section 14, component imaging section 18, operation panel 36, and mounting section 20. Storage section 33 stores mounting condition information 34, offset information 35, or the like. Mounting condition information 34 is information including an arrangement order of mounting components P on board S, identification information (ID) of component P, information on a type of the component, a disposition position (XY coordinate) on board S, and the like. Offset information 35 is information including an offset value indicating an adjustment amount of the height of collection member 23 from reference height Hb of component P when component P is collected from holding member 16. Offset information 35 includes, in addition to the ID of holding member 16, the information on the type of holding member 16, the ID of held component P, and the offset value, information on the collection accuracy indicating the collection state when component P is collected in association with holding member 16. Offset information 35 includes, as offset values, an initial offset value set before the mounting, short-term offset value Ff used in an initial stage of the mounting of component P, production offset value Fp with increased collection accuracy over a long period of time, and the like, and a value with higher collection accuracy is used in the mounting process. The collection accuracy is a value indicating the accuracy of collecting component P by collection member 23, and may include, for example, a distance between center coordinates of collection member 23 and center coordinates of component P, that is, a deviation amount, a rotation angle, or the like. In mounting device 11, as illustrated in FIG. 2, a range between upper limit value Fa and lower limit value Fb is set as offset range F as an allowable range for setting an offset value. Offset range F can be defined as an allowable range of upper surface height H of component P for which the offset value can be set. Upper limit value Fa may be, for example, a value of 10% or 20% (for example, +0.1 mm or the like) of thickness t of component P upward from reference height Hb. Lower limit value Fb may be, for example, a value of 20% or 30% (for example, −0.3 mm or the like) of thickness t of component P downward from reference height Hb.

Operation panel 36 is a unit that exchanges information with an operator, and has display section 37 for displaying a screen and operation section 38 for the operator to operate.

Management device 40 is a computer that manages information of each device of mounting system 10. As illustrated in FIG. 1, management device 40 includes control section 41, storage section 43, display section 47, and input device 48. Control section 41 is configured as a microprocessor centered on CPU 42. Storage section 43 is a device, such as HDD, that stores various data, such as a processing program. Storage section 43 stores mounting condition information 44 as a database including information similar to mounting condition information 34, offset information 45 as a database including information similar to offset information 35, and the like. Mounting condition information 44 and offset information 45 include information of all mounting devices 11 provided in mounting system 10. Display section 47 is a liquid crystal screen that displays various information. Input device 48 includes a keyboard, a mouse, and the like through which the operator inputs various commands.

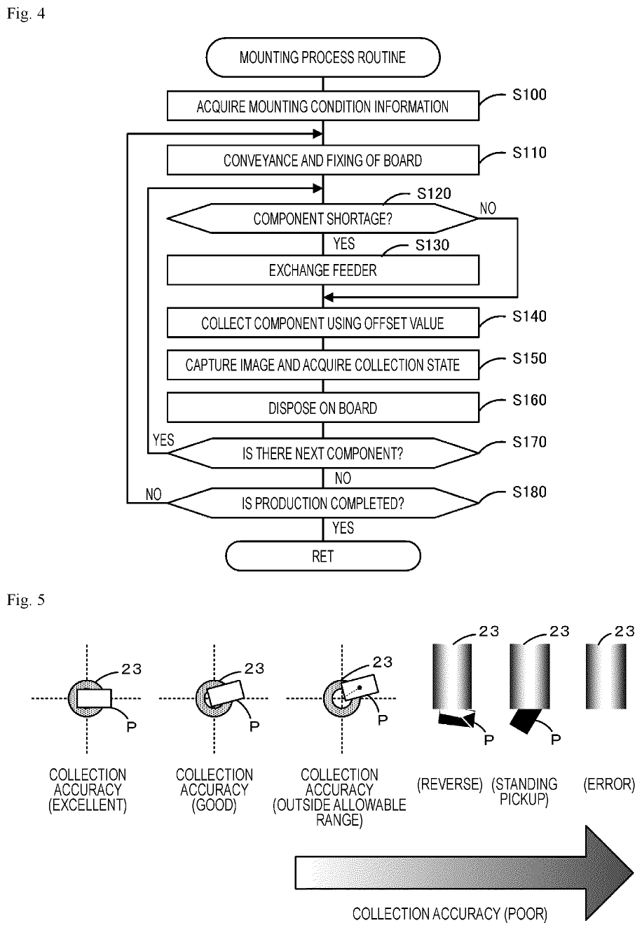

Next, an operation of mounting system 10 of the present embodiment configured as described above, that is, a process of performing a mounting process using an offset value will be described. FIG. 4 is a flowchart illustrating an example of a mounting process routine performed by CPU 32 of control section 31. The routine is stored in storage section 33 and is performed by an instruction from the operator. When this routine is executed, CPU 32 reads and acquires mounting condition information 34 (S100), conveys and fixes board S (S110), and determines whether there is feeder 15 in which a component shortage has occurred (S120). The component shortage determination may be performed every time mounting head 22 collects component P. When the component shortage has occurred, CPU 32 exchanges feeder 15 (S130). The exchange of feeder 15 may be performed by a loader as an automatic exchange device, or may be performed by the operator by notifying the operator. After S130 or when there is no component shortage in S120, CPU 32 causes collection member 23 to collect component P based on the arrangement order of mounting condition information 34 using the offset value (S140). CPU 32 uses the offset value corresponding to component P to lower and/or lift collection member 23 to a position at which a push-in amount (for example, 0.1 mm to 0.3 mm, 0.1 mm to 0.2 mm, or the like) is larger than upper surface height H of component P. Next, CPU 32 causes component imaging section 18 to capture the image of collected component P and acquires the collection state of component P (S150). CPU 32 analyzes the captured image and acquires a deviation amount, a rotation angle, and the like of component P from the center of collection member 23.

FIG. 5 is a diagram illustrating an example of collection accuracy. FIG. 5 illustrates an example in which the collection accuracy deteriorates as the position moves to the right. As illustrated in FIG. 5, a case where there is a positional deviation in which the collection accuracy is out of an allowable range or a collection state such as reverse pickup, standing pickup, suction failure, or the like of component P corresponds to a collection error. In addition, as for the collection state, the mounting process can be performed even in the collection accuracy (good), but it is preferable that component P can be collected at a level of the deviation amount of the collection accuracy (excellent). CPU 32 stores the collection accuracy as the acquired collection state in storage section 33.

After S150, CPU 32 moves collected component P to dispose component P at a predetermined position on board S (S160). At this time, CPU 32 performs a discarding process on component P of the collection error and then performs a process of collecting component P again. Subsequently, CPU 32 determines whether there is next component P to be disposed on board S based on mounting condition information 34 (S170). When there is next component P, CPU 32 performs the processes in and after S120. That is, when there is a component shortage, feeder 15 is exchanged, component P is collected using the offset value corresponding to component P, and the process of disposing component P on board S is repeatedly performed. Conversely, when there is no next component P in S170, CPU 32 determines that the disposition of component P on board S is completed, and determines whether the production of board S is completed (S180). When the production of board S is not completed, CPU 32 assumes that there is next board S, and performs the processes in and after S110. That is, the process of discharging board S on which the mounting is performed, conveying and fixing next board S, and collecting and disposing component P using the offset value is repeatedly performed. Conversely, when the production is completed in S180, CPU 32 ends the routine.

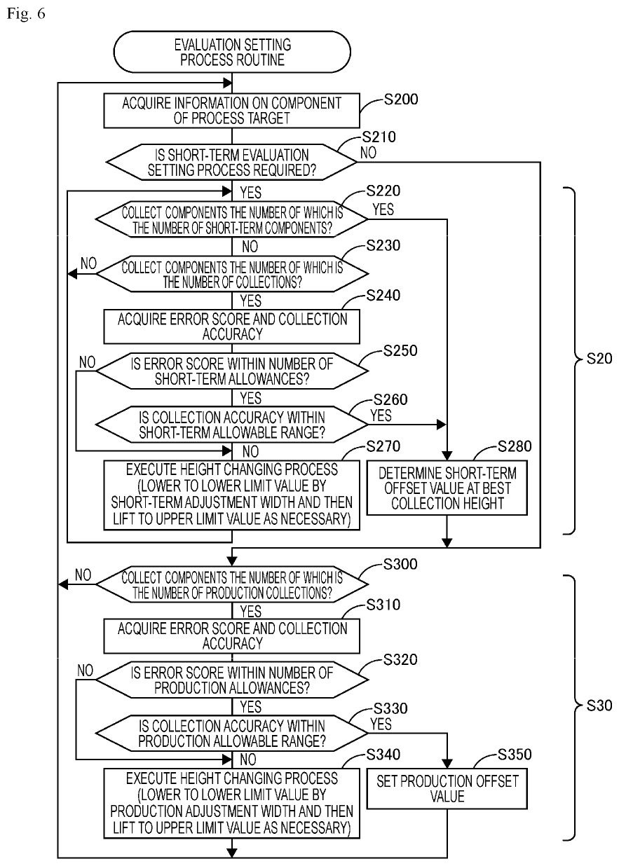

Next, the process of setting the offset value will be described. FIG. 6 is a flowchart illustrating an example of an evaluation setting process routine executed by CPU 32 of control section 31. This routine is stored in storage section 33 and executed in parallel with the mounting process routine. Here, a process of setting an offset value for specific component P held by feeder 15 mounted in a specific slot of component supply section 14 will be described. That is, mounting device 11 executes the setting process of the offset value for each feeder 15 to be mounted. When this routine is executed, CPU 32 acquires information on component P of the process target (S200). Examples of the information on component P include the ID of feeder 15, the ID of component P, the number of mounting achievements of components P, and the like. The number of mounting achievements is, for example, the number of mounting processes performed by mounting device 11 or the like.

Next, CPU 32 determines whether component P requires the short-term evaluation setting process of S20 (S210). CPU 32 may determine that the short-term evaluation setting process is required, for example, after feeder 15 is exchanged and switched to new holding member 16, or when the number of components P is less than the predetermined number of mounting achievements. When holding member 16 is exchanged, the shape of component P or holding section 17 may change, and height H of component P may change. When the number of mounting achievements is small, the offset value may not be sufficiently appropriate. In such a case, CPU 32 determines that the short-term evaluation setting process is required. CPU 32 may make this determination based on any one of the exchange of holding member 16 and the number of mounting achievements, or may make this determination based on other factors. Here, the short-term evaluation setting process refers to a process of roughly obtaining a favorable short-term offset value with the smaller number of short-term components Nf than the production process.

When it is determined that the short-term evaluation setting process is required, CPU 32 determines whether components P the number of which is the number of short-term components Nf are collected in the mounting process (S220). Here, the number of short-term components Nf may be, for example, the number of components smaller than the number of components of the production process, or may be the number of components smaller than the number of production collections Np used in the production evaluation setting process (S30) in which the collection height is evaluated and set in the production process or the total number of components of the production process. The number of short-term components Nf may be, for example, ½ or less, ⅕ or less, 1/10 or less, or 1/100 or less of the total number of components of the production process and/or the number of production collections Np. The number of short-term components Nf may be 5000 or less, more preferably 4000 or less, even more preferably 2000 or less, or 1000 or less. The number of production collections Np is the number of components at a break where evaluation of the collection height for setting production offset value Fp with higher collection accuracy is executed. The number of production collections Np is set to, for example, ⅕ or less, 1/10 or less, 1/100 or less, or the like of the total number of corresponding components P so that evaluation is performed the sufficient number of times. The number of production collections Np is set to a value (for example, 2000) smaller than the total number (for example, 50000) of corresponding components P. The number of production collections Np may be 1000 or more, more preferably 2000 or more, even more preferably 5000 or more, 10000 or more, or 15000 or more. The number of short-term components Nf may be less than or equal to the number of components of 5000, and the number of production collections Np may be greater than or equal to the number of short-term components Nf. For example, the number of short-term components Nf is the total number of components P for which useful short-term offset value Ff can be set with a smaller number of components. In addition, the number of collections Na is the number of components at a break where evaluation of short-term offset value Ff of the collection height is performed, and is included in the number of short-term components Nf. For example, when 20 collection members 23 are mounted on mounting head 22, mounting head 22 collects 500 components P by 25 times of component collection. Here, when the number of short-term components Nf is 2000 and the number of collections Na is 500, offset range F can be divided by short-term adjustment width Af of four stages (see FIG. 8 described later), and short-term offset value Ff can be evaluated and set in four stages in the short-term evaluation setting process. That is, it is possible to evaluate and set more suitable short-term offset value Ff among the four stages using the total number of components P of 2000. Here, a case where the number of short-term components Nf is 2000, the number of collections Na is 500, short-term adjustment width Af is 0.1 mm, offset range F is +0.1 mm to −0.3 mm (|0.4| mm), the number of production collections Np is 2000, and production adjustment width Ap is 0.01 mm will be mainly described.

When components P the number of which is the number of short-term components Nf are not collected in S220, CPU 32 determines whether components P the number of which is the number of collection components Na is collected (S230). When components P the number of which is the number of collections Na are not collected, CPU 32 repeatedly performs the processes in and after S220. That is, CPU 32 stands by until components P the number of which is the number of collections Na within the range of the number of short-term components Nf are collected while repeatedly collecting components P with the currently set offset value (for example, the initial offset value). Conversely, when components P the number of which is the number of collections Na are collected in S230, CPU 32 acquires an error score and the collection accuracy obtained by the number of collections Na (S240). The error score refers to the number of errors that occur when components P the number of which is the number of collections Na are collected. In addition, the collection accuracy may be an average value of the collection accuracy when components P the number of which is the number of collections Na are collected. When acquiring the collection accuracy, CPU 32 may ignore, for example, the collection accuracy of the first number of times (one time, two times, or the like), or need not use the collection accuracy for calculating the average value. In the first collection of components P, since holding member 16 is on the tip side, and holding member 16 may be deformed or component P is not held in a good posture in some cases, it is desirable that collection accuracy be determined by excluding such irregular states.

Next, CPU 32 determines whether the error score is within the number of short-term allowances Xf (S250). The number of short-term allowances Xf is a threshold value of the number of errors allowable in the short-term evaluation setting process, and may be set based on an allowable error rate. For example, when the number of collections Na is 500 and the allowable error rate is 0.2%, the number of short-term allowances Xf is 1, and CPU 32 determines that this step is not allowable if two collection errors occur. When the error score is within the number of short-term allowances Xf, CPU 32 determines that the collection accuracy is at a level where an error is unlikely to occur, and determines whether the collection accuracy acquired in S240 is within short-term allowable range Rf (S260). Short-term allowable range Rf is a threshold value of the collection accuracy allowable in the short-term evaluation setting process, and may be empirically set based on an allowable value of the collection accuracy. Short-term allowable range Rf may be set to a range of the collection accuracy lower than production allowable range Rp based on the collection accuracy allowable in the production evaluation setting process (S30), or may be set to the same level of collection accuracy as production allowable range Rp. Specifically, short-term allowable range Rf may be the collection accuracy (good) or the collection accuracy (best) of FIG. 5.

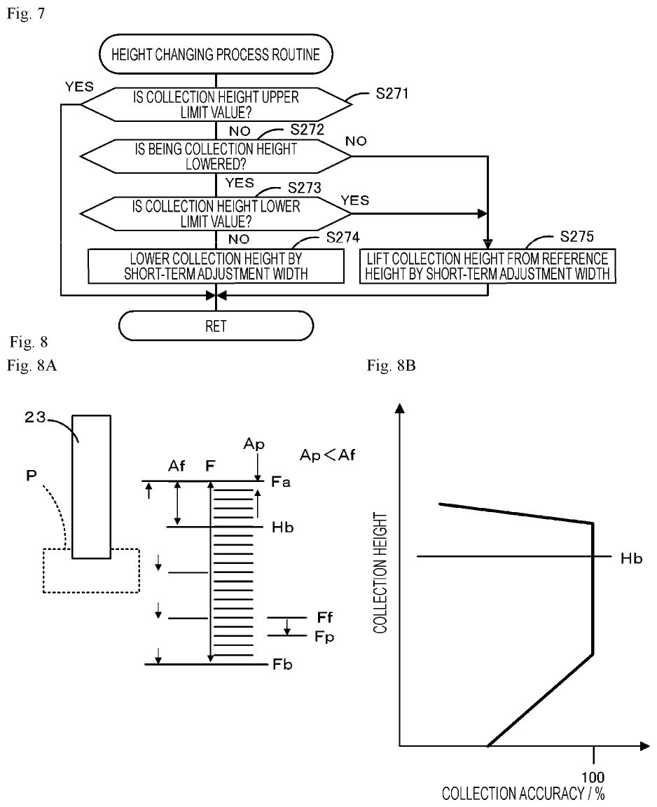

When the collection accuracy exceeds short-term allowable range Rf in S260, or when the error score exceeds the number of short-term allowances Xf in S250, CPU 32 executes a height changing process of adjusting the collection height with short-term adjustment width Af (S270), and executes the processes in and after S220. FIG. 7 is a flowchart illustrating an example of a height changing process routine executed in S270. FIG. 8 is a diagram of allowable ranges of short-term adjustment width Af and production adjustment width Ap, in which FIG. 8A is a diagram of adjustment of the collection height, and FIG. 8B is a relationship diagram between the collection accuracy and the collection height. When this process is started, CPU 32 determines whether the collection height of component P reaches upper limit value Fa (S271). When the collection height does not reach upper limit value Fa, CPU 32 determines whether the collection height is being lowered (S272). When the collection height is being lowered, CPU 32 determines whether the collection height reaches lower limit value Fb (S273). As illustrated in FIG. 8B, the collection accuracy is empirically poor when collection member 23 does not reach the upper surface of component P, and after collection member 23 reaches the upper surface of component P, the decrease of the collection accuracy tends to be gentle even when the pressing amount increases. In accordance with this, in the height changing process, CPU 32 performs a process of lifting collection member 23 from reference height Hb after collection member 23 is completely lowered. When the collection height does not reach lower limit value Fb in S273, CPU 32 sets short-term offset value Ff for lowering the collection height using short-term adjustment width Af (S274). Conversely, when the collection height reaches lower limit value Fb in S273 or when the collection height is not being lowered in S272, CPU 32 sets short-term offset value Ff that lifts the collection height from reference height Hb using short-term adjustment width Af (S275). After S275, after S274, or when the collection height is upper limit value Fa in S271, CPU 32 ends the routine. In the height changing process, a process is performed in which the collection height is lowered to lower limit value Fb using short-term adjustment width Af, and then lifted to upper limit value Fa as necessary (see FIG. 8A). When short-term offset value Ff is changed, component P is collected using the changed value in the mounting process routine, and CPU 32 obtains the error score and the collection accuracy at the offset value in S240. In the height changing process, a provisional short-term offset value Ff that can be changed later is set.

Conversely, when components P the number of which is the number of short-term components Nf are collected in S220, or when the collection accuracy is within short-term allowable range Rf in S260, the offset value corresponding to the collection height indicating the best collection accuracy is determined as short-term offset value Ff (S280). At this time, CPU 32 may set short-term offset value Ff such that the height at which the number of collection errors is smaller in the short-term evaluation setting process becomes the collection height. Further, CPU 32 may set short-term offset value Ff at which the height at which the collection accuracy is higher in the short-term evaluation setting process becomes the collection height. The priority order of the number of errors and the collection accuracy may be an initial value that gives priority to “the number of errors” being small, and may be appropriately set by the operator. In this way, CPU 32 first sets more favorable short-term offset value Ff in offset range F with a smaller number of components using relatively large short-term adjustment width Af. When short-term offset value Ff is determined, CPU 32 executes the mounting process using determined short-term offset value Ff in the mounting process.

Meanwhile, after short-term offset value Ff is determined in S280, or when the short-term evaluation setting process is not required in S210, CPU 32 executes the production evaluation setting process of setting production offset value Fp with higher collection accuracy than the short-term evaluation setting process (S30). In the production evaluation setting process, CPU 32 first determines whether components P the number of which is the number of production collections Np are collected in the mounting process using the current offset value (S300). Here, CPU 32 determines whether 2000 components P are collected. Short-term offset value Ff is initially used as the offset value, and, once updated, production offset value Fp is used. When components P the number of which is the number of production collections Np are collected, CPU 32 assumes that a considerable number of data are accumulated, and acquires the error score and the collection accuracy generated therebetween (S310). The collection accuracy may be an average value as in the short-term evaluation setting process. Next, CPU 32 determines whether the error score is within predetermined the number of production allowances Xp (S320). The number of production allowances Xp is a threshold value of the number of errors allowable in the production evaluation setting process, and may be set based on an allowable error rate. For example, when the number of production collections Np is 2000 and the allowable error rate is 0.1%, the number of production allowances Xp is 2, and CPU 32 determines that this step is not allowable if three collection errors occur.

When the error score is within the predetermined number of production allowances Xp in S320, CPU 32 determines whether the collection accuracy acquired in S310 is within production allowable range Rp (S330). Production allowable range Rp is a threshold value of the collection accuracy allowable in the production evaluation setting process, and may be empirically set based on an allowable value of the collection accuracy. Production allowable range Rp may be the collection accuracy (best) of FIG. 5. When the collection accuracy exceeds production allowable range Rp in S330, or when the error score exceeds the number of production allowances Xp in S320, CPU 32 executes height changing process for adjusting the collection height with production adjustment width Ap (S340). In the height changing process, a process is performed in which short-term adjustment width Af is changed to production adjustment width Ap and production offset value Fp is updated in the height changing process of FIG. 7 described above. In the height changing process, a process is performed in which the collection height is lowered to lower limit value Fb using production adjustment width Ap, and then lifted to upper limit value Fa as necessary (see FIG. 8A). In the height changing process, as illustrated in FIG. 8A, CPU 32 executes a process of obtaining the collection accuracy at a fine collection height using production adjustment width Ap having a smaller adjustment amount.

Conversely, when the collection accuracy is within production allowable range Rp in S330, CPU 32 assumes that the current collection height indicates considerably high collection accuracy, and sets the current offset value to production offset value Fp (S350). After S340, after S350, or when components P the number of which is the number of production collections Np are not collected in S300, CPU 32 executes the processes in and after S200. That is, CPU 32 repeats the process of acquiring the information on component P of the process target and waiting until mounting head 22 collects components P the number of which is the number of production collections Np. In this way, CPU 32 sets more favorable production offset value Fp within offset range F using fine production adjustment width Ap, as the number of components increases. When production offset value Fp is set, CPU 32 continues the mounting process using set production offset value Fp in the mounting process. By performing the production evaluation setting process after performing the short-term evaluation setting process, as illustrated in FIG. 8A, a value with higher collection accuracy is set from short-term offset value Ff to production offset value Fp. Control section 31 may store set short-term offset value Ff and set production offset value Fp in offset information 35 and output offset information 35 to management device 40. Management device 40 updates offset information 45 as a database based on acquired offset information 35.

Here, a correspondence relationship between the elements of the present embodiment and the elements of the present disclosure will be clarified. Component P of the present embodiment corresponds to the component of the present disclosure, holding member 16 corresponds to the holding member, collection member 23 corresponds to the collection member, component supply section 14 corresponds to the component supply section, mounting section 20 corresponds to the mounting section, control section 31 corresponds to the control section, and component imaging section 18 corresponds to the imaging section. Further, the number of short-term components Nf corresponds to the number of short-term components, the number of short-term allowances Xf corresponds to the predetermined number of allowances, short-term offset value Ff corresponds to the short-term offset value, short-term allowable range Rf corresponds to the allowable range, the number of collections Na corresponds to the number of collections, short-term adjustment width Af corresponds to the adjustment width, upper limit value Fa corresponds to the upper limit value, lower limit value Fb corresponds to the lower limit value, the number of production collections Np corresponds to the number of production collections, and production offset value Fp corresponds to the predetermined production offset value. In addition, the processes of S250 and S260 of the present embodiment correspond to the allowance determination of the present disclosure, the process of S270 corresponds to the changing process, the process of S20 corresponds to the short-term evaluation setting process, and the process of S30 corresponds to the production evaluation setting process. In the present embodiment, an example of the setting method of the present disclosure is also clarified by describing the operation of control section 31.

Mounting device 11 of the present embodiment described above includes component supply section 14 that supplies component P from holding member 16 that holds multiple components P, mounting section 20 that includes collection member 23 that collects component P from component supply section 14 and is capable of collecting component P at multiple collection heights, and control section 31 that performs the predetermined allowance determination (S250) by causing mounting section 20 to collect component P at a predetermined collection height within a range of a predetermined number of short-term components Nf, executes the changing process (S270) that repeats changing the collection height using short-term offset value Ff that adjusts the collection height of mounting section 20 when the number of collection errors exceeds the predetermined number of short-term allowances Xf, and performs the short-term evaluation setting process of setting the collection height based on a result of the changing process. Mounting device 11 performs an allowance determination to determine whether the number of collection errors exceeds the predetermined number of short-term allowances Xf within the range of the predetermined number of short-term components Nf, and executes the short-term evaluation setting process to set the collection height based on the result of the changing process to change the collection height. Generally, in the mounting device, a large number of component statistics may be required in order to improve the collection accuracy in the production process. In this mounting device, since a suitable collection height is set by changing the collection height within the range of the predetermined number of short-term components Nf, it is possible to further improve the collection accuracy of component P in the short-term evaluation.

In addition, mounting device 11 includes component supply section 14, mounting section 20, and control section 31 that causes mounting section 20 to collect component P at the predetermined collection height using short-term offset value Ff within the range of the number of short-term components Nf, obtains the collection accuracy with which mounting section 20 collects component P to perform the predetermined allowance determination, executes the changing process of repeatedly changing the collection height using short-term offset value Ff when the obtained collection accuracy is outside short-term allowable range Rf, and executes the short-term evaluation setting process of setting the collection height based on the result of the changing process. In mounting device 11, since a suitable collection height is set by changing the collection height within the range of the number of short-term components Nf, it is possible to further improve the collection accuracy of component P in the short-term evaluation.

Further, control section 31 sets, as the collection height, a height at which the positional deviation amount of the component is smaller as the collection accuracy. In mounting device 11, the collection accuracy of component P can be further improved based on the positional deviation amount of the component. Furthermore, control section 31 performs the allowance determination (S250 and S260) for each of the predetermined number of collections Na within the number of short-term components Nf, and sets the collection height (S280) when the number of collected components P reaches the number of short-term components Nf even if it is less than the number of collections Na (S230). In mounting device 11, the short-term evaluation can be suitably executed. Then, the collection height has upper limit value Fa and lower limit value Fb, and when changing the collection height, control section 31 lowers the collection height toward lower limit value Fb using short-term offset value Ff, and then lifts the collection height toward upper limit value Fa as necessary to set the collection height. In general, in the mounting device, compared to a state in which collection member 23 is pushed into component P, there is a tendency that the collection accuracy decreases, and the occurrence rate of the collection error increases when collection member 23 is separated from component P. In mounting device 11, it is easy to obtain a more suitable collection height by first lowering the collecting position.

Furthermore, after setting the collection height in the short-term evaluation setting process (S20), control section 31 executes the changing process of repeating changing the collection height using predetermined production offset value Fp with reference to the predetermined number of production collections Np larger than the number of short-term components Nf in the production process, and executes the production evaluation setting process (S30) of setting the collection height based on the result of the changing process executed within the range of the number of production collections Np. In mounting device 11, a roughly preferable collection height can be set by the number of short-term components Nf by the short-term evaluation setting process, and thereafter, a more accurate collection height can be set by the larger number of production collections Np by the production evaluation setting process. Short-term offset value Ff has short-term adjustment width Af larger than production adjustment width Ap of production offset value Fp. In mounting device 11, in the short-term evaluation setting process, a rough tendency of the collection state can be obtained using a larger adjustment width of the collection height, and thus a preferable collection height can be set in a shorter period of time. In addition, in mounting device 11, the number of short-term components Nf is 2000, which is less than 5000, and the number of production collections Np is 2000, which is equal to or greater than the number of short-term components Nf. The number of short-term components Nf is preferably a smaller value for short-term evaluation, and the number of production collections Np is preferably a larger value for accuracy improvement. In addition, control section 31 executes the short-term evaluation setting process on components P after the exchange of holding member 16 in component supply section 14 and/or the number of components P collected by mounting section 20 is less than the predetermined number of achievements. Mounting device 11 can execute the short-term evaluation process when the necessity is high. Further, mounting device 11 includes component imaging section 18 that captures the image of the component collected by mounting section 20, and control section 31 performs the allowance determination based on the captured image of component P. In mounting device 11, the collection state of component P can be determined based on the captured image.

In addition, mounting system 10 includes mounting device 11 and management device 40 that manages mounting device 11. Since mounting system 10 includes the above-described mounting device 11, it is possible to further improve the collection accuracy of components P in the short-term evaluation by changing the collection height within the range of the predetermined number of short-term components Nf and setting the suitable collection height. In addition, in the setting method described in FIGS. 6 and 7, similarly to mounting device 11 described above, since a suitable collection height is set by changing the collection height within the range of the predetermined number of short-term components Nf, it is possible to further improve the collection accuracy of component P in the short-term evaluation.

It is needless to say that the present disclosure is not limited in any way to the above-described embodiments, and the present disclosure can be embodied in various aspects as long as the aspects fall within the technical scope of the present disclosure.

For example, in the above-described embodiments, the short-term evaluation setting process of S20 is executed in the initial stage of the production process, but is not particularly limited to this, and the short-term evaluation setting process may be executed independently. For example, only the short-term evaluation setting process may be executed as the performance evaluation of the device. Specifically, the processes of S200 to S280 of the evaluation setting process routine may be executed. At this time, if the state in which component P is collected is grasped, the process of disposing component P on board S may be omitted. Also in mounting device 11, since a suitable collection height is set by changing the collection height within the range of the predetermined number of short-term components Nf, it is possible to further improve the collection accuracy of component P in the short-term evaluation.

In the embodiments described above, short-term offset value Ff is set, and the collection height is set and determined based on the error score of the collection and the collection accuracy, but is not particularly limited to this, and the collection height may be set and determined based on any one of the error score and the collection accuracy. Also in mounting device 11, since a suitable collection height is set by changing the collection height within the range of the predetermined number of short-term components Nf, it is possible to further improve the collection accuracy of component P in the short-term evaluation.

In the above-described embodiments, as the collection accuracy, a height at which the positional deviation amount of component P is smaller is set as the collection height, but is not particularly limited to this as long as it is possible to set the collection height to further improve the collection accuracy, and factors other than the positional deviation amount may be used. A sensor that checks a component in a pickup state from the side may be provided for the collection accuracy.

In the above-described embodiments, the allowance determination of S250 and S260 is performed for each of the number of collections Na within the range of the number of short-term components Nf, but it is not particularly limited to the number of collections Na, and may be set freely. It is preferable to set the number of collections Na to a multiple of the number of components (here, 20) that can be collected at one time by mounting head 22 for simplification of the process. Mounting head 22 is described as having 20 collection members 23 mounted thereon, but the number is not particularly limited to this, and may be set to the number corresponding to mounting head 22 and component P, such as 2,12, or 18. Alternatively, in the above-described embodiments, when the number of collected components P reaches the predetermined number of short-term components Nf, the collection height is set even if the number of collected components P is less than the number of collections Na, but it is not particularly limited to this, and after reaching the number of short-term components Nf, the collection height may be set after collecting components P the number of which is the number of collections Na.

In the above-described embodiments, the collection height is lowered toward lower limit value Fb using short-term offset value Ff, and then the collection height is lifted toward upper limit value Fa as necessary to set the collection height, but is not particularly limited to this, and the collection height may be set by lifting the collection height toward upper limit value Fa and then lowering the collection height toward lower limit value Fb. It is preferable to lower the collection height first from the viewpoint of shortening the time required to improve the collection accuracy.

In the above-described embodiment, in S210, the short-term evaluation setting process is executed after the exchange of holding member 16 in component supply section 14 and/or for the component for which the number of collections by mounting section 20 is less than the predetermined number of achievements, but is not particularly limited to this, and in the initial stage of the mounting process, the short-term evaluation setting process may be executed for any component P. Also in mounting device 11, since a suitable collection height is set by changing the collection height within the range of the predetermined number of short-term components Nf, it is possible to further improve the collection accuracy of component P in the short-term evaluation. In addition, in S210, control section 31 may omit the determination of any one of components P after the exchange of holding member 16 and components P less than the number of achievements, or may determine another factor instead of or in addition to this.

In the above-described embodiment, the collection error or the collection accuracy is obtained based on the captured image captured by component imaging section 18, but is not particularly limited to this, and for example, the imaging section that captures the image of component P disposed on board S may be provided in mounting head 22 or the like, and the collection error or the collection accuracy may be obtained from the captured image of component P disposed on board S. Also in mounting device 11, the collection accuracy of component P can be further improved in the short-term evaluation.

In the embodiments described above, the present disclosure has been described as mounting device 11, but the present disclosure is not particularly limited to this, may be described as a setting method, and this setting method can also be implemented as a program executed by the computer.

### INDUSTRIAL APPLICABILITY

The mounting device, the mounting system, and the setting method of the present disclosure can be used, for example, in the field of mounting electronic components.

### REFERENCE SIGNS LIST

10 mounting system, 11 mounting device, 12 board processing section, 14 component supply section, 15 feeder, 16 holding member, 17 holding section, 18 component imaging section, 20 mounting section, 21 head moving section, 22 mounting head, 23 collection member, 24 lifting and lowering mechanism, 31 control section, 32 CPU, 33 storage section, 34 mounting condition information, 35 offset information, 36 operation panel, 37 display section, 38 operation section, 40 management device, 41 control section, 42 CPU, 43 storage section, 44 mounting condition information, 45 offset information, 47 display section, 48 input device, Af short-term adjustment width, Ap production adjustment width, F offset range, Fa upper limit value, Fb lower limit value, Ff short-term offset value, Fp production offset value, H upper surface height, Hb reference height, Na the number of collections, Nf the number of short-term components, Np the number of production collections, P component, Rf short-term allowable range, Rp production allowable range, S board, t thickness, Xf the number of short-term allowances, Xp the number of production allowances

1. A mounting device comprising:
a component supply section configured to supply a component from a holding member that holds multiple components;
a mounting section including a collection member configured to collect the component from the component supply section, the mounting section being capable of collecting the component at multiple collection heights; and
a control section configured to perform a predetermined allowance determination by causing the mounting section to collect the component at a predetermined collection height within a range of a predetermined number of short-term components, execute a changing process of repeatedly changing the collection height using a short-term offset value for adjusting the collection height of the mounting section when the number of collection errors exceeds the predetermined number of allowances, and execute a short-term evaluation setting process of setting the collection height based on a result of the changing process.

2. The mounting device according to claim 1, wherein the control section causes the mounting section to collect the component at the predetermined collection height within the range of the predetermined number of short-term components, obtains collection accuracy with which the mounting section collects the component to perform a predetermined allowance determination, executes a changing process of repeatedly changing the collection height using the short-term offset value when the obtained collection accuracy is outside an allowable range, and executes a short-term evaluation setting process of setting the collection height based on a result of the changing process.

3. A mounting device comprising:
a component supply section configured to supply a component from a holding member that holds multiple components;
a mounting section including a collection member configured to collect the component from the component supply section, the mounting section being capable of collecting the component at multiple collection heights; and
a control section configured to cause the mounting section to collect the component at a predetermined collection height within a range of the predetermined number of short-term components, obtain collection accuracy with which the mounting section collects the component to perform a predetermined allowance determination, execute a changing process of repeatedly changing the collection height using a short-term offset value when the obtained collection accuracy is outside an allowable range, and execute a short-term evaluation setting process of setting the collection height based on a result of the changing process.

4. The mounting device according to claim 2, wherein the control section sets a height at which a positional deviation amount of the component as the collection accuracy is smaller as the collection height.

5. The mounting device according to claim 1, wherein the control section performs the allowance determination for each predetermined number of collections within the predetermined number of short-term components, and sets the collection height even if the number of collected components is less than the number of collections when the number of collected components reaches the predetermined number of short-term components.

6. The mounting device according to claim 1, wherein the collection height has an upper limit value and a lower limit value, and
when changing the collection height, the control section lowers the collection height toward the lower limit value using the short-term offset value, and then lifts the collection height toward the upper limit value as necessary to set the collection height.

7. The mounting device according to claim 1, wherein, after setting the collection height in the short-term evaluation setting process, the control section executes a changing process of repeating changing the collection height using a predetermined production offset value with reference to a predetermined number of production collections larger than the predetermined number of short-term components in a production process, and executes a production evaluation setting process of setting the collection height based on the result of the changing process executed within a range of the number of production collections.

8. The mounting device according to claim 7, wherein the short-term offset value has an adjustment width larger than the production offset value.

9. The mounting device according to claim 7, wherein the predetermined number of short-term components is less than or equal to the number of components of 5000, and
the predetermined number of production collections is greater than or equal to the number of short-term components.

10. The mounting device according to claim 1, wherein the control section executes the short-term evaluation setting process after exchange of the holding member in the component supply section and/or for the component for which the number of collections by the mounting section is less than the predetermined number of achievements.

11. The mounting device according to claim 1, further comprising:
an imaging section configured to capture an image of the component collected by the mounting section,
wherein the control section performs the allowance determination based on the captured image of the component.

12. A mounting system comprising:
the mounting device according to claim 1; and
a management device configured to manage the mounting device.

13. A setting method executed by a mounting device including a component supply section configured to supply a component from a holding member that holds multiple components, and a mounting section including a collection member configured to collect the component from the component supply section, the mounting section being capable of collecting the component at multiple collection heights, the setting method comprising:
a step of performing a predetermined allowance determination by causing the mounting section to collect the component at a predetermined collection height within a range of a predetermined number of short-term components, executing a changing process of repeatedly changing the collection height using a short-term offset value for adjusting the collection height of the mounting section when the number of collection errors exceeds the predetermined number of allowances, and executing a short-term evaluation setting process of setting the collection height based on a result of the changing process; and/or
a step of causing the mounting section to collect the component at the predetermined collection height within the range of the predetermined number of short-term components, obtaining collection accuracy with which the mounting section collects the component to perform a predetermined allowance determination, executing a changing process of repeatedly changing the collection height using the short-term offset value when the obtained collection accuracy is outside an allowable range, and executing a short-term evaluation setting process of setting the collection height based on a result of the changing process.
